(19) United States
(12) Patent Application Publication
(10) Pub. No.: US 2026/0371823 A1
(43) Pub. Date: Nov. 19, 2026

(54) DISPLAY DEVICE, METHOD OF MANUFACTURING DISPLAY DEVICE, AND ELECTRONIC DEVICE

(71) Applicant: Samsung Display Co., Ltd., Yongin-si (KR)

(72) Inventors: SANGHYUN YUN, Yongin-si (KR); YOUNJOO RYU, Yongin-si (KR); JUNHO SIM, Yongin-si (KR); PIL SOON HONG, Yongin-si (KR)

(21) Appl. No.: 19/542,842

(22) Filed: Feb. 18, 2026

(30) Foreign Application Priority Data
May 19, 2025 (KR) 10-2025-0064469

(51) Int. Cl. H10H 29/855; H10H 29/01

(52) U.S. Cl. CPC H10H 29/8552; H10H 29/011; H10H 29/012; H10H 29/0363

(57) ABSTRACT

A display device includes: a substrate including an emission area and a non-emission area adjacent to the emission area; a light-emitting element in the emission area on the substrate; and a plurality of light blocking patterns on the light-emitting element and spaced apart from each other. Each of the plurality of light blocking patterns has a width satisfying the following equation: X=H/D×1/A×k, where X denotes the width of each of the plurality of light blocking patterns, H denotes a height of each of the plurality of light blocking patterns, D denotes a distance between the plurality of light blocking patterns, A denotes an optical density of the plurality of light blocking patterns, and k is a constant in a range from about 0.35 to about 0.60.

This application claims priority to Korean Patent Application No. 10-2025-0064469, filed on May 19, 2025, and all the benefits accruing therefrom under 35 U.S.C. § 119, the content of which in its entirety is herein incorporated by reference.

### BACKGROUND

### 1. Field

The present disclosure relates generally to a display device. More particularly, the present disclosure relates to a display device that provides visual information, a method of manufacturing the display device, and an electronic device including the display device.

### 2. Description of the Related Art

A display device is a device that displays an image for providing visual information to a user. The display device may display an image with a wide viewing angle. Alternatively, the viewing angle of the image displayed on the display device may be desired to be limited for security reasons or to improve the image reflection.

For example, in the case of a display device for an automobile, an image displayed on a display device positioned in front of the passenger may be provided to the driver, or an image displayed on a display device positioned in front of the driver may be reflected from a front windshield of the automobile and provided to the driver. Accordingly, the viewing angle of the display device may be desired to be limited in a left-right direction or an up-down direction.

### SUMMARY

Embodiments provide a display device that controls the viewing angle.

Embodiments provide a method of manufacturing the display device.

Embodiments provide an electronic device including the display device.

A display device according to an embodiment of the present disclosure includes: a

substrate including an emission area and a non-emission area adjacent to the emission area; a light-emitting element in the emission area on the substrate; and a plurality of light blocking patterns on the light-emitting element and spaced apart from each other. In such an embodiment, each of the plurality of light blocking patterns has a width satisfying the following equation: X=H/D×1/A×k, where, X denotes the width of each of the plurality of light blocking patterns, H denotes a height of each of the plurality of light blocking patterns, D denotes a distance between the plurality of light blocking patterns, A denotes an optical density of the plurality of light blocking patterns, and k is a constant in a range from about 0.35 to about 0.60.

In an embodiment, the height of each of the plurality of light blocking patterns and the distance between the plurality of light blocking patterns may satisfy the following inequation: H/D>2.79, where H denotes the height of each of the plurality of light blocking patterns and D denotes the distance between the plurality of light blocking patterns.

In an embodiment, the width of each of the light blocking patterns may be in a range from about 0.97 micrometer (μm) to about 1.75 μm.

In an embodiment, the optical density of the plurality of light blocking patterns may be in a range from about 0.9 to about 1.67.

In an embodiment, the plurality of light blocking patterns may include a black pigment and a blue pigment. In such an embodiment, a ratio of a content of the black pigment and a content of the blue pigment may be in a range from about 6:4 to about 8:2.

In an embodiment, in a plan view, the plurality of light blocking patterns may cover about 20% to about 30% of the emission area.

In an embodiment, a reflectance of the plurality of light blocking patterns may be less than or equal to about 5%.

In an embodiment, light emitted at a viewing angle of greater than or equal to about 30° may be blocked.

A method of manufacturing a display device according to an embodiment of the present disclosure includes: forming a light-emitting element in an emission area on a substrate; forming a plurality of preliminary light blocking patterns on the light-emitting element; and forming a plurality of light blocking patterns, which are spaced apart from each other, by removing a portion of the plurality of preliminary light blocking patterns. In such an embodiment, each of the plurality of light blocking patterns has a width satisfying the following equation: X=H/D×1/A×k, where X denotes the width of each of the plurality of light blocking patterns, H denotes a height of each of the plurality of light blocking patterns, D denotes a distance between the plurality of light blocking patterns, A denotes an optical density of the plurality of light blocking patterns, and k is a constant in a range from about 0.35 to about 0.60.

In an embodiment, the height of each of the plurality of light blocking patterns and the distance between the plurality of light blocking patterns may satisfy the following inequality:

H/D>2.79, where H denotes the height of each of the plurality of light blocking patterns and D denotes the distance between the plurality of light blocking patterns.

In an embodiment, the width of each of the light blocking patterns may be in a range form about 0.97 μm to about 1.75 μm.

In an embodiment, the optical density of the plurality of light blocking patterns may be in a range form about 0.9 to about 1.67.

In an embodiment, in a plan view, the plurality of light blocking patterns may cover about 20% to about 30% of the emission area.

In an embodiment, light emitted at a viewing angle of greater than or equal to about 30° may be blocked.

In an embodiment, the forming the plurality of light blocking patterns may include: forming a plurality of first preliminary transmission patterns on the light-emitting element; forming a light blocking layer covering the plurality of first preliminary transmission patterns; forming the plurality of preliminary light blocking patterns by removing a portion of the light blocking layer; forming the plurality of light blocking patterns by removing the portion of the plurality of preliminary light blocking patterns; and forming a plurality of second preliminary transmission patterns between the plurality of light blocking patterns to form a transmission pattern.

In an embodiment, the portion of the light blocking layer may be removed through an ashing process in the forming the plurality of preliminary light blocking patterns.

An electronic device according to an embodiment of the present disclosure includes: a display device; and a processor which transmits an image data signal and an input control signal to the display device. In such an embodiment, the display device includes: a substrate including an emission area and a non-emission area adjacent to the emission area; a light-emitting element in the emission area on the substrate; and a plurality of light blocking patterns on the light-emitting element and spaced apart from each other. In such an embodiment, each of the plurality of light blocking patterns has a width satisfying the following equation: X=H/D×1/A×k, where X denotes the width of each of the plurality of light blocking patterns, H denotes a height of each of the plurality of light blocking patterns, D denotes a distance between the plurality of light blocking patterns, A denotes an optical density of the plurality of light blocking patterns, and k is a constant in a range from about 0.35 to about 0.60.

In an embodiment, the height of each of the plurality of light blocking patterns and the distance between the plurality of light blocking patterns may satisfy the following inequality: H/D>2.79, where H denotes the height of each of the plurality of light blocking patterns and D denotes the distance between the plurality of light blocking patterns.

In an embodiment, the width of each of the light blocking patterns may be in a range form about 0.97 μm to about 1.75 μm.

In an embodiment, the optical density of the plurality of light blocking patterns may be in a range form about 0.9 to about 1.67.

A display device according to embodiments of the present disclosure may include light blocking patterns disposed on a light-emitting element. In such embodiments, the light blocking patterns may absorb light emitted from the light-emitting element, thereby effectively controlling the viewing angle of the display device.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is an enlarged plan view illustrating an embodiment of a pixel of the display device of FIG. 1.

FIG. 3 is a cross-sectional view taken along line I-I′ of FIG. 2.

FIG. 4 is an enlarged cross-sectional view illustrating the area A of FIG. 3.

FIGS. 5, 6, 7, 8, 9, and 10 are cross-sectional views illustrating a method of manufacturing the display device of FIG. 3.

FIG. 11 is a schematic view illustrating an exterior of a vehicle according to an embodiment of the present disclosure.

FIG. 12 is a schematic view illustrating an interior space of the vehicle of FIG. 11.

FIG. 13 is a block diagram illustrating an electronic device according to an embodiment of the present disclosure.

FIG. 14 is a schematic view illustrating electronic devices according to embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings. The same reference numerals are used for the same components in the drawings, and any repetitive detailed descriptions of the same components will be omitted or simplified.

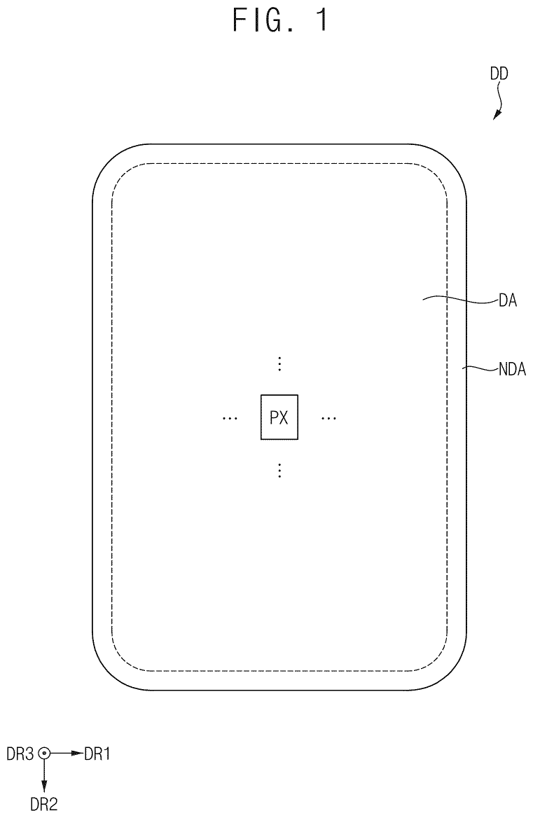

FIG. 1 is a plan view illustrating a display device according to an embodiment of the present disclosure.

Referring to FIG. 1, an embodiment of a display device DD may include a display area DA and a non-display area NDA.

The display area DA may be an area that displays an image. Pixels PX may be disposed in the display area DA. The pixels PX may be repeatedly arranged along a first direction DR1 and a second direction DR2 intersecting the first direction DR1 in a plan view. Herein, the second direction DR2 may be perpendicular to the first direction DR1. Each of the pixels PX may emit light, and accordingly, the display area DA may display an image. In an embodiment, for example, the display area DA may display an image in a third direction DR3 intersecting each of the first direction DR1 and the second direction DR2. In an embodiment, for example, the third direction DR3 may be perpendicular to each of the first direction DR1 and the second direction DR2. The third direction DR3 may be a thickness direction of the display device DD.

The non-display area NDA may be an area that does not display an image. The non-display area NDA may be positioned around the display area DA. In an embodiment, for example, the non-display area NDA may surround the display area DA in a plan view or when viewed in the third direction DR3. A driver for driving the pixels PX may be disposed in the non-display area NDA. The driver may provide a signal or voltage to the pixels PX. In an embodiment, for example, the driver may include a data driver, a gate driver, a timing controller, or the like. The pixels PX may emit light based on the signal or the voltage received from the driver.

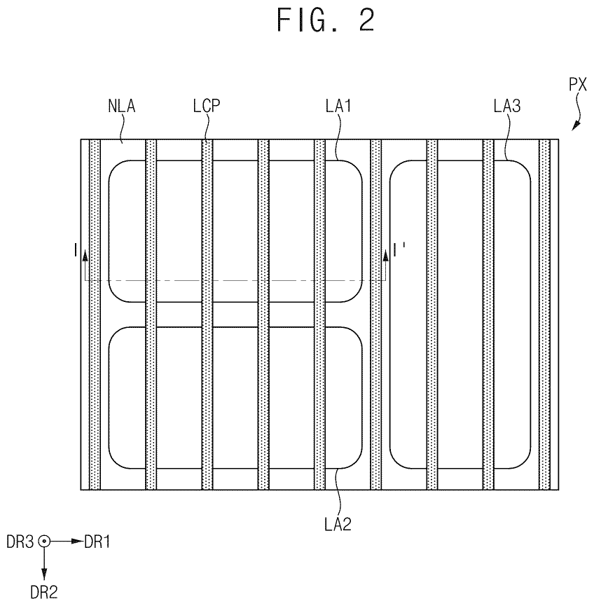

FIG. 2 is an enlarged plan view illustrating an embodiment of a pixel of the display device of FIG. 1.

Referring to FIGS. 1 and 2, in an embodiment, each of the pixels PX may include an emission area and a non-emission area NLA.

The emission area may be an area that emits light. The emission area may include a first emission area LA1, a second emission area LA2, and a third emission area LA3, each emitting light.

In an embodiment, the first to third emission areas LA1, LA2, and LA3 may emit light of different wavelength bands. The first emission area LA1 may emit a first light, the second emission area LA2 may emit a second light, and the third emission area LA3 may emit a third light. In an embodiment, for example, the first light may be light of a red wavelength band, the second light may be light of a green wavelength band, and the third light may be light of a blue wavelength band. However, the present disclosure is not limited thereto, and each of the first to third lights may be light of various wavelength bands. As the first to third lights are combined, each of the pixels PX may emit light of various colors.

In an embodiment, as shown in FIG. 2, the second emission area LA2 may be adjacent to the first emission area LA1 in the second direction DR2, and the third emission area LA3 may be adjacent to the first and second emission areas LA1 and LA2 in the first direction DR1, but this is merely an example and the present disclosure is not limited thereto. In an embodiment, for example, the arrangement of the first to third emission areas LA1, LA2, and LA3 may be variously changed, such as the first to third emission areas LA1, LA2, and LA3 being arranged adjacent to each other along the first direction DR1.

In an embodiment, as shown in FIG. 2, each of the first to third emission areas LA1, LA2, and LA3 may include a single emission area, but this is merely an example and the present disclosure is not limited thereto. In another embodiment, for example, each of the first to third emission areas LA1, LA2, and LA3 may include two or more emission areas.

The non-emission area NLA may be an area that does not emit light. The non-emission area NLA may surround the emission area in a plan view. The non-emission area NLA may partition the first to third emission areas LA1, LA2, and LA3.

In an embodiment, the display device DD may include light blocking patterns LCP. Each of the light blocking patterns LCP may extend in one direction, and the light blocking patterns LCP may be spaced apart from each other. In an embodiment, for example, the light blocking patterns LCP may be arranged side by side in a plan view, and may be parallel to each other. In an embodiment, for example, each of the light blocking patterns LCP may extend in the second direction DR2, and the light blocking patterns LCP may be spaced apart from each other in the first direction DR1. However, this is merely an example, and the present disclosure is not limited thereto, and the arrangement of the light blocking patterns LCP may be variously changed. In another embodiment, for example, each of the light blocking patterns LCP may extend in the first direction DR1, and the light blocking patterns LCP may be spaced apart from each other in the second direction DR2.

In an embodiment, the light blocking patterns LCP may be disposed in the first to third emission areas LA1, LA2, and LA3 and the non-emission area NLA. The light blocking patterns LCP may overlap the first to third emission areas LA1, LA2, and LA3 and the non-emission area NLA in a plan view. The light blocking patterns LCP may control or limit the viewing angle of light emitted from each of the first to third emission areas LA1, LA2, and LA3. In an embodiment, for example, some (e.g., at least one) of the light blocking patterns LCP may extend in the second direction DR2 and may overlap the first to third emission areas LA1, LA2, and LA3 and the non-emission area NLA in a plan view, and other some (e.g., at least anther one) of the light blocking patterns LCP may extend in the second direction DR2 and may overlap only with the non-emission area NLA in a plan view.

However, this is merely an example and the present disclosure is not limited thereto, and the arrangement of the light blocking patterns LCP may be variously changed. In an embodiment, for example, in a plan view, the light blocking patterns LCP may overlap at least one of the first to third emission areas LA1, LA2, and LA3 and may be spaced apart from other areas.

In an embodiment, an area (or a size) of an area overlapping the light blocking patterns LCP in a plan view among the first to third emission areas LA1, LA2, and LA3 may be in a range from about 20% to about 30%. In a plan view, the light blocking patterns LCP may be disposed in (e.g., cover) about 20% to about 30% of the first to third emission areas LA1, LA2, and LA3, and may not be disposed in (i.e., may not overlap) about 70% to about 80% of the first to third emission areas LA1, LA2, and LA3. That is, in a plan view, an area in which the light blocking patterns LCP are disposed (or occupied) in the first to third emission areas LA1, LA2, and LA3 may be in a range from about 20% to about 30% of the first to third emission areas LA1, LA2, and LA3, and an area in which the light blocking patterns LCP are not disposed (or occupied) in the first to third emission areas LA1, LA2, and LA3 may be in a range from about 70% to about 80% of the first to third emission areas LA1, LA2, and LA3.

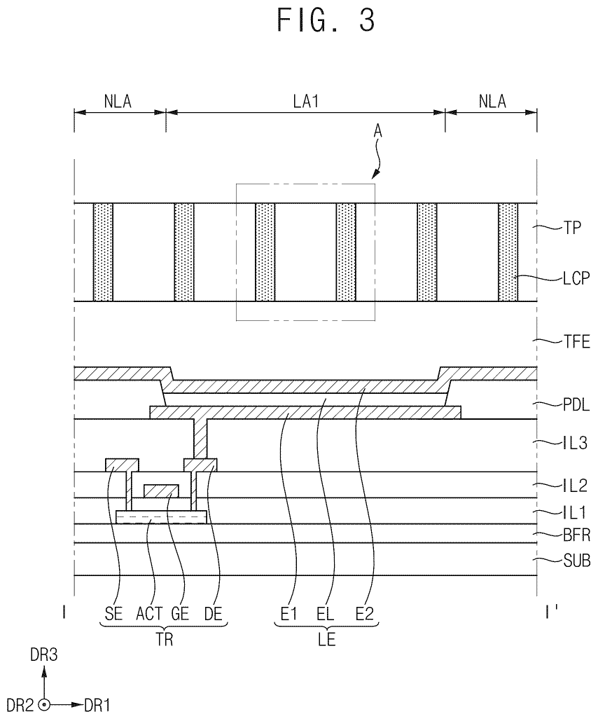

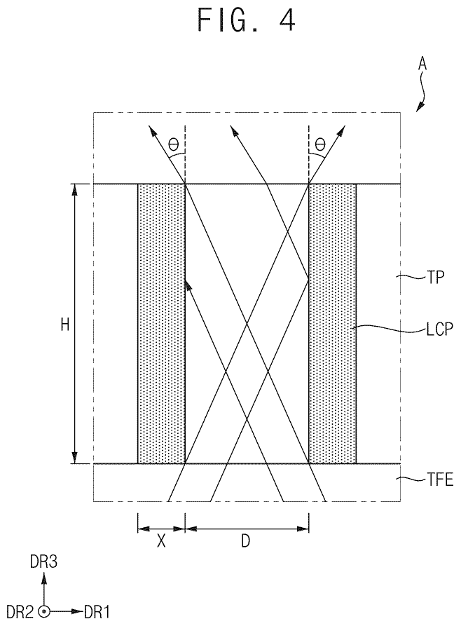

FIG. 3 is a cross-sectional view taken along line I-I′ of FIG. 2. FIG. 4 is an enlarged cross-sectional view illustrating the area A of FIG. 3.

In FIG. 3, only the cross-sectional structure of the first emission area LA1 is illustrated for convenience of illustration and description. The cross-sectional structure of each of the second emission area LA2 and the third emission area LA3 may be substantially the same or similar to the cross-sectional structure of the first emission area LA1. Therefore, the features of the cross-sectional structure of each of the second emission area LA2 and the third emission area LA3 is the same as the features of the cross-sectional structure of the first emission area LA1 described below.

Referring to FIGS. 3 and 4, an embodiment of the display device DD may include a substrate SUB, a buffer layer BFR, a driving element TR, first to third insulating layers IL1, IL2, and IL3, a light-emitting element LE, a pixel defining layer PDL, an encapsulation layer TFE, the light blocking patterns LCP, and a transmission pattern TP. The driving element TR may include an active pattern ACT, a gate electrode GE, a source electrode SE, and a drain electrode DE, and the light-emitting element LE may include a first electrode E1, a light-emitting layer EL, and a second electrode E2.

The substrate SUB may include a transparent material or an opaque material. Examples of a material that may be used as the substrate SUB may include plastic, glass, quartz, and the like. These may be used alone or in combination with each other.

The buffer layer BFR may be disposed on the substrate SUB. The buffer layer BFR may effectively prevent diffusion of metal atoms, impurities, or the like. The buffer layer BFR may include an inorganic material including at least one selected from silicon oxide (SiOₓ), silicon nitride (SiNₓ), silicon oxynitride (SiOₓN_{y}), and the like. These may be used alone or in combination with each other.

The active pattern ACT may be disposed on the buffer layer BFR. The active pattern ACT may include a source area, a drain area, and a channel area between the source area and the drain area. The active pattern ACT may include a silicon semiconductor material or an oxide semiconductor material. Examples of the silicon semiconductor material may include amorphous silicon, polycrystalline silicon, and the like. Examples of the oxide semiconductor material may include indium gallium zinc oxide (IGZO), indium tin zinc oxide (ITZO), and the like. These may be used alone or in combination with each other.

The first insulating layer IL1 may be disposed on the active pattern ACT, and may cover at least a portion of the active pattern ACT. The first insulating layer IL1 may include an inorganic material including at least one selected from silicon oxide, silicon nitride, silicon oxynitride, and the like. These may be used alone or in combination with each other.

The gate electrode GE may be disposed on the first insulating layer IL1. The gate electrode GE may overlap the channel area of the active pattern ACT in a plan view or in the third direction DR3. The gate electrode GE may include at least one selected from a metal, an alloy, a conductive metal oxide, a conductive metal nitride, a transparent conductive material, and the like. These may be used alone or in combination with each other.

The second insulating layer IL2 may be disposed on the gate electrode GE, and may cover the gate electrode GE. The second insulating layer IL2 may include an inorganic material including at least one selected from silicon oxide, silicon nitride, silicon oxynitride, and the like. These may be used alone or in combination with each other.

The source electrode SE and the drain electrode DE may be disposed on the second insulating layer IL2. The source electrode SE may be connected to the source area of the active pattern ACT through a first contact hole that penetrates the first and second insulating layers IL1 and IL2. The drain electrode DE may be connected to the drain area of the active pattern ACT through a second contact hole that penetrates (or is defined or formed through) the first and second insulating layers IL1 and IL2. In ani embodiment, for example, each of the source electrode SE and the drain electrode DE may include at least one selected from a metal, an alloy, a metal nitride, a conductive metal oxide, a transparent conductive material, and the like. These may be used alone or in combination with each other.

The active pattern ACT, the gate electrode GE, the source electrode SE, and the drain electrode DE may define the driving element TR. Accordingly, the driving element TR may be disposed on the substrate SUB.

The third insulating layer IL3 may be disposed on the source electrode SE and the drain electrode DE, and may cover the source electrode SE and the drain electrode DE. The third insulating layer IL3 may include an organic material including at least one selected from a phenolic resin, an acrylic resin, a polyimide resin, a polyamide resin, a siloxane resin, an epoxy resin, and the like. These may be used alone or in combination with each other.

The first electrode E1 may be disposed on the third insulating layer IL3. The first electrode E1 may be electrically connected to the driving element TR. In an embodiment, for example, the first electrode E1 may be connected to the drain electrode DE (or the source electrode SE) through a contact hole that penetrates the third insulating layer IL3. The first electrode E1 may include at least one selected from a metal, an alloy, a metal nitride, a conductive metal oxide, a transparent conductive material, and the like. These may be used alone or in combination with each other. In an embodiment, for example, the first electrode E1 may function as an anode.

The pixel defining layer PDL may be disposed on the third insulating layer IL3. The pixel defining layer PDL may overlap the non-emission area NLA in a plan view. The pixel defining layer PDL may cover opposite sides of the first electrode E1, and may define an opening that exposes a portion of an upper surface of the first electrode E1. The pixel defining layer PDL may include an organic material including at least one selected from a polyimide resin, an epoxy resin, a siloxane resin, and the like, or an inorganic material including at least one selected from a silicon oxide, a silicon nitride, a silicon oxynitride, and the like. These may be used alone or in combination with each other.

The light-emitting layer EL may be disposed on the first electrode E1. The light-emitting layer EL may be disposed in the opening of the pixel defining layer PDL. The light-emitting layer EL may include a material that emits light of a preset color. In an embodiment, for example, the light-emitting layer E) may include a material that emits the first light.

The second electrode E2 may be disposed on the light-emitting layer EL and the pixel defining layer PDL. In an embodiment, for example, the second electrode E2 may continuously extend in the first to third emission areas LA1, LA2, and LA3 and the non-emission area NLA. The second electrode E2 may include a metal, an alloy, a conductive metal oxide, a conductive metal nitride, a transparent conductive material, and the like. These may be used alone or in combination with each other. In an embodiment, for example, the second electrode E2 may function as a cathode.

The first electrode E1, the light-emitting layer EL and the second electrode E2 may define the light-emitting element LE. The light-emitting element LE may define the first emission area LA1. Accordingly, the light-emitting element LE may be disposed in the first emission area LA1 on the substrate SUB. The light-emitting element LE may be electrically connected to the driving element TR.

The encapsulation layer TFE may be disposed on the common electrode CE. The encapsulation layer TFE may effectively prevent impurities, moisture, external air, or the like from penetrating into the light-emitting element LE from the outside. The encapsulation layer TFE may include at least one inorganic layer and at least one organic layer. In an embodiment, for example, the organic layer and the inorganic layer may be alternately stacked with each other.

The light blocking patterns LCP may be disposed on the encapsulation layer TFE. In an embodiment, the light blocking patterns LCP may be disposed on the first emission area LA1 and the non-emission area NLA. In an embodiment, for example, the light blocking patterns LCP may be disposed on the light-emitting element LE and may overlap the light-emitting element LE in a plan view.

In an embodiment, an optical density (OD) of the light blocking patterns LCP may be in a range from about 0.9 to about 1.67 per micrometer (/μm) depending on the pattern design and material properties. The optical density of the light blocking patterns LCP may be adjusted depending on a material included in the light blocking patterns LCP. The light blocking patterns LCP may include a light blocking material (e.g., a material that absorbs light). In an embodiment, for example, the light blocking patterns LCP may include at least one selected from an organic material including a black pigment, a black dye, and the like.

Light emitted from the light-emitting element LE may be incident on the light blocking patterns LCP or may pass between the light blocking patterns LCP. Light incident on the light blocking patterns LCP may be reflected from the light blocking patterns LCP, absorbed by the light blocking patterns LCP, or may transmit through the light blocking patterns LCP.

In an embodiment, most of the light incident on the light blocking patterns LCP may be absorbed by the light blocking patterns LCP. A viewing angle θ of the display device DD may be controlled or determined by the light blocking patterns LCP. Here, the viewing angle θ may be defined as an angle formed by a user's viewing direction and an imaginary straight line in the third direction DR3. For example, when the user views the display device DD in the third direction DR3 (i.e., a vertical direction), the viewing angle θ may be about 0°.

The light blocking patterns LCP may absorb most of the light emitted at the viewing angle θ greater than or equal to a cut-off angle (e.g., a preset cut-off angle), thereby blocking the light from being emitted to the outside of the display device DD at the viewing angle θ greater than or equal to the cut-off angle. The light blocking patterns LCP may control or limit the viewing angle θ of the display device DD by preventing the light from being viewed by the user at the viewing angle θ greater than or equal to the cut-off angle.

In an embodiment, when less than or equal to about 3% of the light emitted from the light-emitting element LE at the viewing angle θ is visible to the user, it may be defined that the light at the viewing angle θ is not visible to the user and the viewing angle θ is blocked. For example, when less than or equal to about 3% of the light emitted from the light-emitting element LE at the viewing angle θ of the cut-off angle is visible to the user, the viewing angle θ greater than or equal to the cut-off angle may be defined as being blocked. For example, when a specific angle at which the viewing angle θ is blocked is less than or equal to the cut-off angle, the viewing angle θ greater than or equal to the specific angle is blocked, and thus the cut-off angle of the display device DD may be defined as being satisfied. In this case, the cut-off angle of the viewing angle θ may be variously set depending on the use, purpose, and the like of the display device DD.

In an embodiment, where the display device DD is applied to a vehicle, the cut-off angle of the viewing angle θ may be set to about 30°. The light blocking patterns LCP may be disposed to absorb most of the light emitted at the viewing angle θ greater than or equal to about 30°, and the light emitted at the viewing angle θ greater than or equal to about 30° may be substantially invisible to the user by the light blocking patterns LCP. At the viewing angle θ of greater than or equal to about 30°, less than or equal to about 3% of the light emitted by the light-emitting element LE may be visible to the user, and the viewing angle θ of greater than or equal to about 30° of the display device DD may be blocked. For example, when the viewing angle θ is blocked at a specific angle of less than or equal to about 30°, it may be defined that the cut-off angle of about 30° of the display device DD is satisfied.

In an embodiment, the light blocking patterns LCP may include a mixture of a lactam black pigment and a blue pigment. In an embodiment, for example, a ratio of a content of the lactam black pigment and a content of the blue pigment in the light blocking patterns LCP may be in a range from about 6:4 to about 8:2, e.g., about 7:3. When the ratio of a content of the lactam black pigment and a content of the blue pigment is within the above range, the absorption rate of the light blocking patterns LCP in the entire wavelength range may be relatively high, and the reflectance may be relatively low. When the reflectance of the light blocking patterns LCP is reduced, light visible to the outside through the light blocking patterns LCP may be reduced.

When comparing a case in which the reflectance of the light blocking patterns LCP is large and a case in which the reflectance of the light blocking patterns LCP is small at a same viewing angle θ greater than or equal to the cut-off angle, the light recognized by the user may be further reduced when the reflectance of the light blocking patterns LCP is small. That is, as the reflectance of the light blocking patterns LCP decreases, the light reflected by the light blocking patterns LCP and emitted to the outside may be reduced, and the viewing angle θ greater than or equal to the cut-off angle of the display device DD may be more effectively blocked. In an embodiment, the reflectance of the light blocking patterns LCP may be less than or equal to about 5%. In this case, the viewing angle θ of the display device DD may be more easily controlled, which may be more desired in terms of the viewing angle θ.

In an embodiment, for example, the reflectance of the light blocking patterns LCP may be in a range from about 4.79% to about 6.3%. In an embodiment, for example, in the light blocking patterns LCP, when the ratio of the content of the lactam black pigment and the content of the blue pigment is about 7:3, the optical density of the light blocking patterns LCP may be about 1.0, and the reflectance of the light blocking patterns LCP may be about 4.96%.

However, the present disclosure is not limited thereto, and the light blocking patterns LCP may include various materials having relatively low transmittance and reflectance, and relatively high absorption, which can effectively control the viewing angle θ.

In an embodiment, each of the light blocking patterns LCP may have a width X in the first direction DR1 and a height H in the third direction DR3. Among the light blocking patterns LCP, adjacent light blocking patterns LCP may be spaced apart from each other by a distance D in the first direction DR1.

In an embodiment, the width X of each of the light blocking patterns LCP may satisfy the equation (hereinafter, will be referred to as “Formula 1”) below.

X=H/D×1/A×k [Formula 1]

In the Formula 1, A denotes the optical density of the light blocking patterns LCP, and k is a constant in a range from about 0.35 to about 0.60. k is a constant related to the optical density of the light blocking patterns LCP.

In an embodiment, a range of the width X of each of the light blocking patterns LCP satisfying the Formula 1 may be in a range form about 0.97 μm to about 1.75 μm. In an embodiment, for example, when an area in a plan view in which the light blocking patterns LCP are disposed in the first to third emission areas LA1, LA2, and LA3 is about 20% of the first to third emission areas LA1, LA2, and LA3, the width X of each of the light blocking patterns LCP may be about 0.97 μm. In an embodiment, for example, when the area in a plan view in which the light blocking patterns LCP are disposed in the first to third emission areas LA1, LA2, and LA3 is about 30% of the first to third emission areas LA1, LA2, and LA3, the width X of each of the light blocking patterns LCP may be about 1.75 μm.

In addition, in an embodiment, the height H of each of the light blocking patterns LCP and the distance D of the light blocking patterns LCP may satisfy the inequality (hereinafter, will be referred to as “Formula 2”) below.

H/D>2.79 [Formula 2]

In an embodiment, each of the light blocking patterns LCP satisfying the Formula 1 and the Formula 2 may have a high aspect ratio.

The transmission pattern TP may be disposed on the encapsulation layer TFE. The transmission pattern TP may be disposed between the light blocking patterns LCP. The transmission pattern TP may fill a space between adjacent light blocking patterns LCP. The transmission pattern TP may include an organic material, including at least one selected from an epoxy resin, a siloxane resin, a polyimide resin, a photoresist, and the like. The transmission pattern TP may be optically transparent. Light emitted from the light-emitting element LE and incident on the transmission pattern TP may transmit through the transmission pattern TP.

Table 1 below shows an evaluation of the light blocking patterns according to embodiments and comparative examples. Specifically, Table 1 below shows an angle at which the viewing angle is blocked by the light blocking pattern according to the embodiments and the comparative examples when the cut-off angle of the viewing angle is set to about 30° Each of the embodiments is a light blocking pattern LCP satisfying the Formula 1 and the Formula 2. In addition, each of the embodiments is the light blocking pattern LCP satisfying a range of the width X satisfying the Formula 1. Each of the comparative examples is a light blocking pattern that does not satisfy at least one selected from the Formula 1, the Formula 2, and the range of the width X.

TABLE 1

| | | | | an angle at |
|---|---|---|---|---|
| | a height of | a width of | a distance | which the |
| | the light | the light | between the | viewing |
| | blocking | blocking | light blocking | angle is |
| | pattern | pattern | patterns | blocked |
| Embodiment 1 | 10 μm | 1.50 μm | 3.50 μm | 22° |
| Embodiment 2 | 10 μm | 1.00 μm | 3.50 μm | 26° |
| Comparative | 10 μm | 0.50 μm | 3.50 μm | 36° |
| Example 1 | | | | |
| Comparative | 5 μm | 1.00 μm | 3.50 μm | 61° |
| Example 2 | | | | |
| Comparative | 5 μm | 0.44 μm | 1.75 μm | 22° |
| Example 3 | | | | |

In the Embodiment 1, the height H of the light blocking pattern LCP is about 10 μm, the width X of the light blocking pattern LCP is about 1.50 μm, and the distance D between the light blocking patterns LCP is about 3.50 μm. In this case, the angle at which the viewing angle is blocked is about 22°, which was confirmed to satisfy an angle below the set cut-off angle (e.g., about) 30°.

In the Embodiment 2, the height H of the light blocking pattern LCP is about 10 μm, the width X of the light blocking pattern LCP is about 1.00 μm, and the distance D between the light blocking patterns LCP is about 3.50 μm. In this case, the angle at which the viewing angle is blocked is about 26°, which was confirmed to satisfy an angle below the set cut-off angle (e.g., about) 30°.

In the Comparative Example 1, the height of the light blocking pattern is about 10 μm, the width of the light blocking pattern is about 0.5 μm, and the distance between the light blocking patterns is about 3.50 μm. In this case, the angle at which the viewing angle is blocked is about 36° which is greater than the set cut-off angle (e.g., about) 30°, and it was confirmed that the angle does not satisfy the cut-off angle. In addition, it was confirmed that the light blocking pattern does not satisfy the Formula 1 and the range of the width X that satisfies the Formula 1.

In the Comparative Example 2, the height of the light blocking pattern is about 5 μm, the width of the light blocking pattern is about 1.0 μm, and the distance between the light blocking patterns is about 3.50 μm. In this case, the angle at which the viewing angle is blocked is about 61° which is greater than the set cut-off angle (e.g., about) 30°, and it was confirmed that the angle does not satisfy the cut-off angle. In addition, it was confirmed that the light blocking pattern does not satisfy the Formula 1 and the Formula 2.

In the Comparative Example 3, the height of the light blocking pattern is about 5 μm, the width of the light blocking pattern is about 0.44 μm, and the distance between the light blocking patterns is about 1.75 μm. In this case, the angle at which the viewing angle is blocked is about 22° which is less than the set cut-off angle (e.g., about) 30°, and it was confirmed that the angle satisfies the cut-off angle. However, it was confirmed that the light blocking pattern does not satisfy the Formula 1 and the range of the width X that satisfies the Formula 1.

As in the Embodiment 1 and the Embodiment 2, when the light blocking pattern LCP satisfies the Formula 1, the Formula 2, and the range of the width X that satisfies the Formula 1, it can be confirmed that the angle at which the viewing angle is blocked satisfies the cut-off angle. As in the Comparative Example 1 and the Comparative Example 2, when the light blocking pattern does not satisfy at least one of the Formula 1, the Formula 2, and the range of the width X that satisfies the Formula 1, it can be confirmed that the angle at which the viewing angle is blocked does not satisfy the cut-off angle. In addition, as in the Comparative Example 3, even when the angle at which the viewing angle is blocked satisfies the cut-off angle, it can be confirmed that the light blocking pattern does not satisfy at least one of the Formula 1, the Formula 2, and the range of the width X that satisfies the Formula 1. The display device DD according to an embodiment of the present disclosure may include the light blocking patterns LCP disposed on the light-emitting element LE. The light blocking patterns LCP may absorb light emitted from the light-emitting element LE, and accordingly, the viewing angle of the display device DD may be effectively controlled.

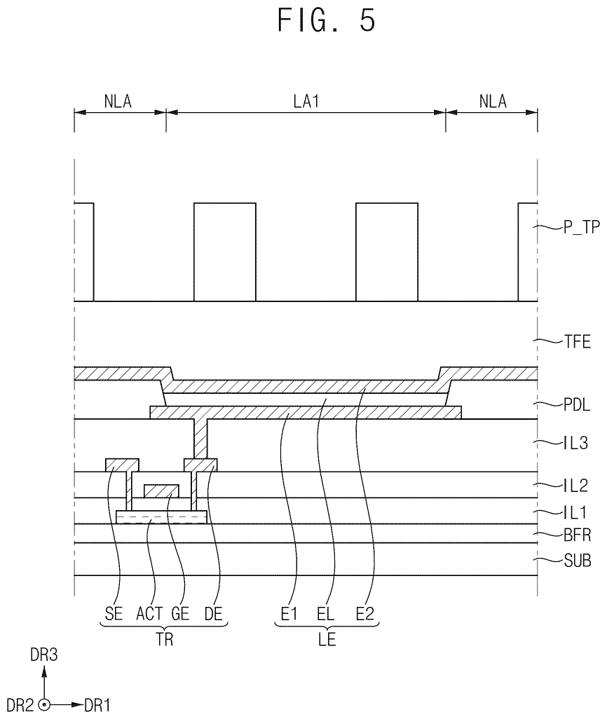

FIGS. 5, 6, 7, 8, 9, and 10 are cross-sectional views illustrating a method of manufacturing the display device of FIG. 3. An embodiment of the method of manufacturing the display device shown in FIGS. 5 to 10 may be a method of manufacturing the display device DD described above with reference to FIGS. 1 to 4. Hereinafter, any repetitive detailed descriptions of the same or like elements as those described above will be omitted or simplified.

Referring to FIG. 5, in an embodiment of a method of manufacturing the display device, first preliminary transmission patterns P_TP may be formed on the encapsulation layer TFE. The first preliminary transmission patterns P_TP may be spaced apart from each other. The first preliminary transmission patterns P_TP may include an organic material.

In an embodiment, for example, the first preliminary transmission patterns P_TP may be formed by forming a preliminary transmission layer and patterning the preliminary transmission layer through a photolithography process. In another embodiment, for example, the first preliminary transmission patterns P_TP may be formed by forming a preliminary transmission layer, and etching the preliminary transmission layer using a hard mask.

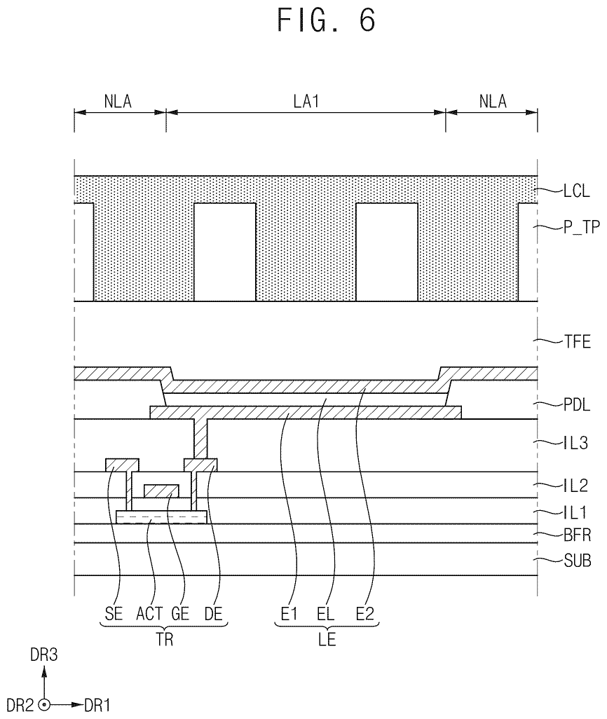

Referring to FIG. 6, in an embodiment of a method of manufacturing the display device, a light blocking layer LCL may be formed on the encapsulation layer TFE. The light blocking layer LCL may cover the first preliminary transmission patterns P_TP. The light blocking layer LCL may cover an upper surface and a side surface of each of the first preliminary transmission patterns P_TP, and may fill a space between the first preliminary transmission patterns P_TP. The light blocking layer LCL may include a light blocking material.

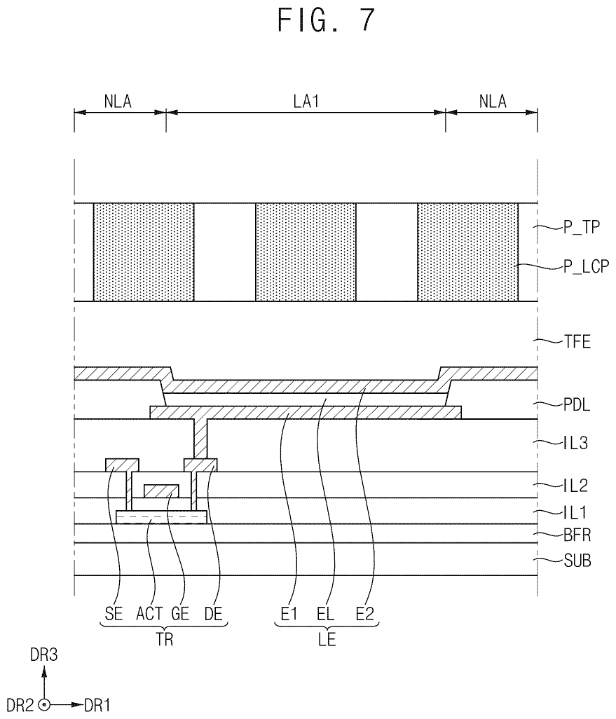

Referring further to FIG. 7, in an embodiment of a method of manufacturing the display device, a portion of the light blocking layer LCL may be removed to form preliminary light blocking patterns P_LCP. The preliminary light blocking patterns P_LCP may be spaced apart from each other. The preliminary light blocking patterns P_LCP may fill the space between the first preliminary transmission patterns P_TP.

In an embodiment, for example, a portion of the light blocking layer LCL formed on the upper surfaces of the first preliminary transparent patterns P_TP may be removed through an oxygen (O₂) ashing process to form the preliminary light blocking patterns P_LCP. In such an embodiment, the manufacturing process may be simplified and the cost may be reduced. In another embodiment, for example, a portion of the light blocking layer LCL formed on the upper surfaces of the first preliminary transparent patterns P_TP may be removed through a chemical mechanical polishing (CMP) process to form the preliminary light blocking patterns P_LCP.

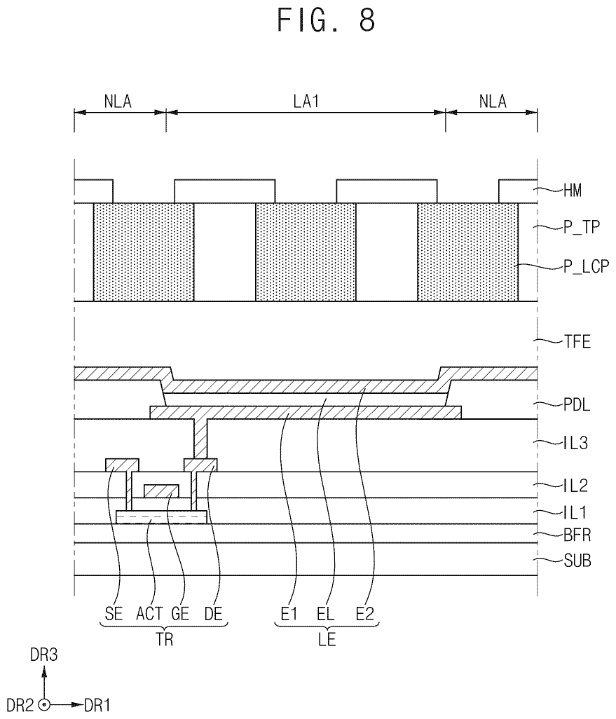

Referring to FIG. 8, in an embodiment of a method of manufacturing the display device, a hard mask HM may be formed on the first preliminary transmission patterns P_TP and the preliminary light blocking patterns P_LCP. In an embodiment, for example, the hard mask HM may include at least one selected from a metal, a transparent conductive material, an inorganic material, and the like.

The hard mask HM may cover the upper surface of each of the first preliminary transmission patterns P_TP and a portion of an upper surface of each of the preliminary light blocking patterns P_LCP. The hard mask HM may define openings that expose at least a portion of the upper surface of each of the preliminary light blocking patterns P_LCP.

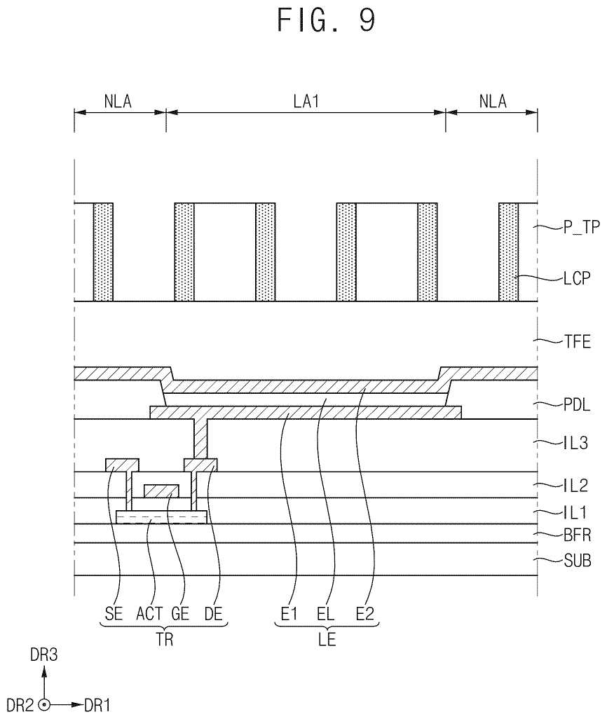

Referring further to FIG. 9, in an embodiment of a method of manufacturing the display device, a portion of the preliminary light blocking patterns P_LCP may be removed using the hard mask HM to form the light blocking patterns LCP. In an embodiment, for example, a portion of the preliminary light blocking patterns P_LCP exposed by the hard mask HM may be etched to form the light blocking patterns LCP. By removing the portion of the preliminary light blocking patterns P_LCP, the light blocking patterns LCP may define openings that expose one side surface of each of the light blocking patterns LCP. After the light blocking patterns LCP are formed, the hard mask HM may be removed.

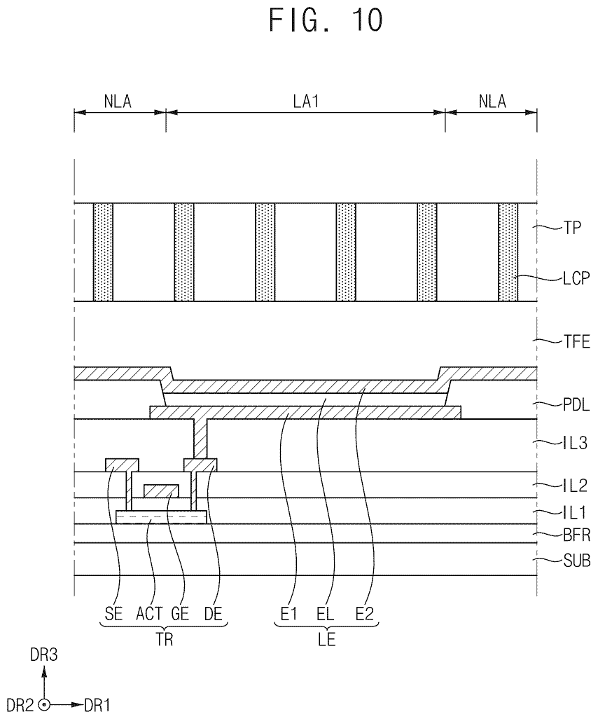

Referring further to FIG. 10, in an embodiment of a method of manufacturing the display device, the transmission pattern TP may be formed on the encapsulation layer TFE. Second preliminary transmission patterns may be formed in the openings defined by the light blocking patterns LCP to form the transmission pattern TP. The second preliminary transmission patterns may include an organic material. In an embodiment, for example, the second preliminary transmission patterns may include a same material as the first preliminary transmission patterns P_TP.

The transmission pattern TP may fill a space between the light blocking patterns LCP spaced apart from each other, and accordingly, the display device DD illustrated in FIG. 3 may be manufactured.

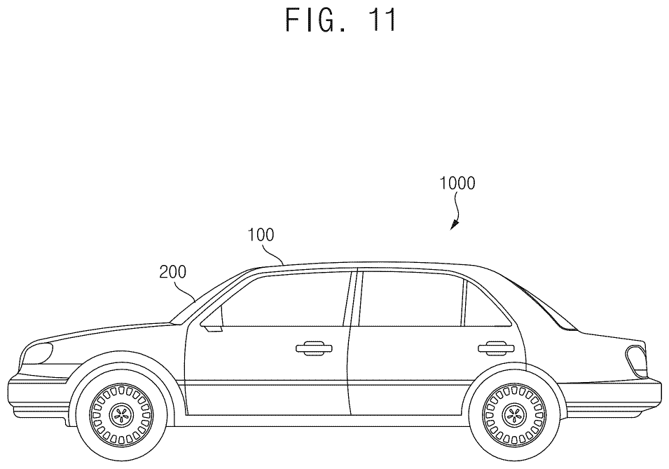

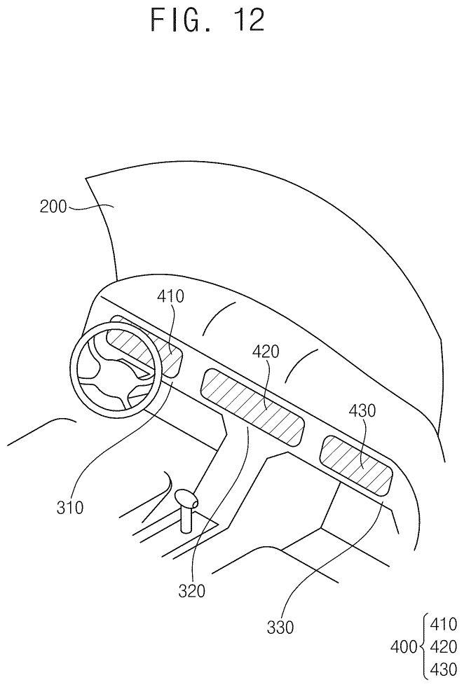

FIG. 11 is a schematic view illustrating an exterior of a vehicle according to an embodiment of the present disclosure. FIG. 12 is a schematic view illustrating an interior space of the vehicle of FIG. 11.

Referring to FIGS. 11 and 12, a vehicle 1000 may be an apparatus that moves a transported object, e.g., a human, an object, an animal, etc. from a starting point to a destination. In an embodiment, for example, the vehicle 1000 may include a three-wheeled or four-wheeled automotive, construction equipment, a two-wheeled automotive, a motorized apparatus, a bicycle, a train running on railroad tracks, a ship running on an ocean or a river, and the like.

The vehicle 1000 may include a body 100 and a chassis.

The body 100 may form an exterior of the vehicle 1000 and define an interior space in which a driver and a passenger ride. In an embodiment, for example, the body 100 may include a front window glass 200, a bonnet, a roof panel, a rear panel, a trunk, or the like. The chassis may include a mechanical apparatus necessary for driving. In an embodiment, for example, the chassis may include a power generation apparatus, a power transmission apparatus, a driving apparatus, a steering apparatus, a braking apparatus, a suspension apparatus, a transmission apparatus, a fuel apparatus, or the like.

The vehicle 1000 may include a cluster 310, a center fascia 320, a passenger seat dashboard 330, and a display device 400.

The cluster 310 may be positioned in front of a steering wheel. The cluster 310 may include a tachometer, a speedometer, a coolant thermometer, a fuel gauge, a turn signal indicator, a high beam indicator, a warning light, a seat belt warning light, an odometer, an automatic transmission selector lever indicator, a door open warning light, an engine oil warning light, a low fuel warning light, or the like.

The center fascia 320 may be adjacent to one side of the cluster 310. A control panel having a plurality of buttons for adjusting an audio apparatus, an air conditioning apparatus, and a seat heater may be disposed on the center fascia 320.

The passenger seat dashboard 330 may be adjacent to one side of the center fascia 320. In an embodiment, for example, the passenger seat dashboard 330 may be spaced apart from the cluster 310 by the center fascia 320. In an embodiment, the cluster 310 may be disposed corresponding to the driver's seat, and the passenger seat dashboard 330 may be disposed corresponding to the passenger seat.

The display device 400 may be disposed in the indoor space. The display device 400 may correspond to the display device DD described above with reference to FIGS. 1 to 4. That is, the display device 400 may have a structure substantially identical or similar to a structure to the display device DD described above with reference to FIGS. 1 to 4.

The display device 400 may be disposed on at least one of the cluster 310, the center fascia 320, and the passenger seat dashboard 330. The display device 400 may include at least one of a first display device 410 disposed on the cluster 310, a second display device 420 disposed on the center fascia 320, and a third display device 430 disposed on the passenger seat dashboard 330. However, the present disclosure is not limited thereto, and the arrangement of the display device 400 may be variously changed. In an embodiment, for example, the display device 400 may be disposed on other components of the vehicle 1000, e.g., on the front window glass 200, on a rearview mirror, and the like.

In an embodiment, for example, the first display device 410 may be disposed on the cluster 310 to provide the driver with vehicle information, speed information, or the like. The second display device 420 may be disposed on the center fascia 320 to provide map information, information regarding vehicle settings, or the like. The third display device 430 may be disposed on the passenger seat dashboard 330 to provide entertainment information and the like to the passenger. However, the present disclosure is not limited thereto, and the information provided by the first to third display devices 410, 420, and 430 may be variously changed.

In an embodiment, the first to third display devices 410, 420, and 430 may minimize light traveling toward the front window glass 200. In an embodiment, for example, the first to third display devices 410, 420, and 430 may absorb or block light emitted toward the front window glass 200 at an angle greater than or equal to a cut-off angle (e.g., the predetermined cut-off angle of the viewing angle θ of FIG. 4). By controlling the viewing angles of the first to third display devices 410, 420, and 430 in the vertical direction, a problem of the image displayed by the first to third display devices 410, 420, and 430 being reflected from the front window glass 200 and provided to the driver, thereby interfering with the driver's forward driving view, may be effectively prevented.

In an embodiment, the third display device 430 may minimize light traveling toward the driver's seat. In an embodiment, for example, the third display device 430 may absorb or block light emitted toward the driver's seat at an angle greater than or equal to a cut-off angle (e.g., the predetermined cut-off angle of the viewing angle θ of FIG. 4). By controlling the viewing angle of the third display device 430 in the left-right direction, a problem of the image displayed on the third display device 430 being provided to the driver, thereby interfering with the driver's driving view, may be prevented.

In an embodiment, as shown in FIG. 12, the first to third display devices 410, 420, and 430 may be spaced apart from each other, but the present disclosure is not limited thereto. In another embodiment, for example, the first to third display devices 410, 420, and 430 may be connected to each other.

The display device DD according to an embodiment of the present disclosure may be applied to a variety of electronic devices. An electronic device according to an embodiment of the present disclosure may include the display device described above, and may further include modules or devices having other additional functions in addition to the display device.

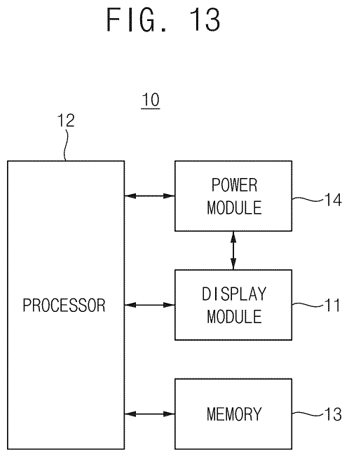

FIG. 13 is a block diagram illustrating an electronic device according to an embodiment of the present disclosure.

Referring to FIG. 13, an electronic device 10 according to an embodiment may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data information used for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power used for operation of the electronic device 10.

At least one of the components of the electronic device 10 described above may be included in the display device according to the embodiments described above. In addition, some of the individual modules that are functionally included in one module may be included in the display device and others may be provided separately from the display device. In an embodiment, for example, the display device may include the display module 11, and the processor 12, the memory 13, and the power module 14 may be provided in the form of other devices in the electronic device 10 other than the display device.

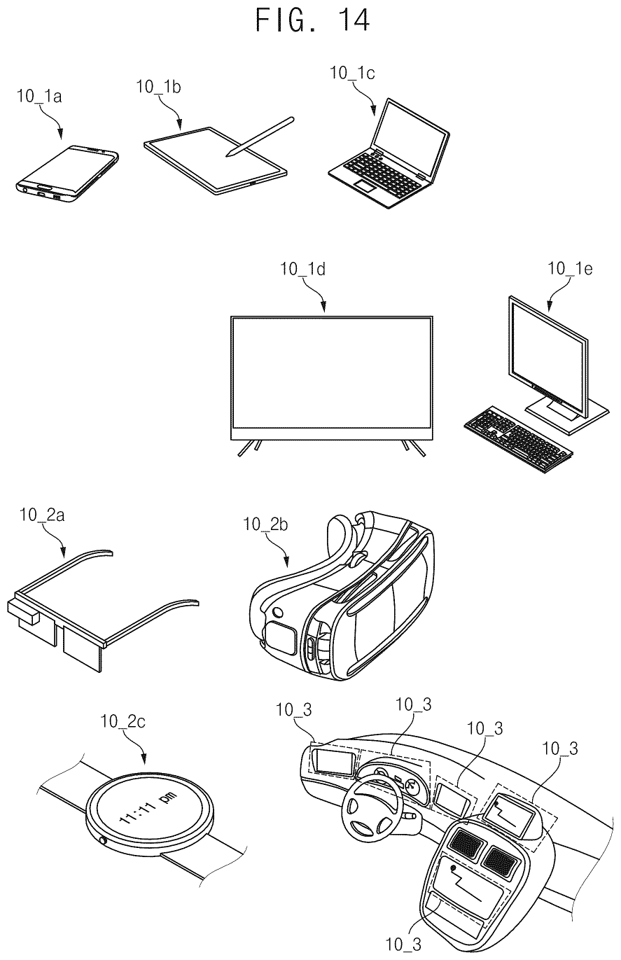

FIG. 14 is a schematic view illustrating electronic devices according to embodiments of the present disclosure.

Referring to FIG. 14, various electronic devices to which a display device according to the embodiments is applied may include image display electronic devices such as a smartphones 10_1a, a tablet personal computer (PC) 10_1b, a laptop computer 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a center information display (CID) which may be disposed on a instrument panel, a center fascia, and a dashboard of an automobile and a room mirror display, or the like.

The present disclosure may be applied to various display devices, for example, display devices for vehicles, ships and aircraft, portable communication devices, display devices for exhibition or information transmission, medical display devices, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising an emission area and a non-emission area adjacent to the emission area;
a light-emitting element in the emission area on the substrate; and
a plurality of light blocking patterns on the light-emitting element and spaced apart from each other, each of the plurality of light blocking patterns having a width satisfying the following equation:
X=H/D×1/A×k,
wherein
X denotes the width of each of the plurality of light blocking patterns,
H denotes a height of each of the plurality of light blocking patterns,
D denotes a distance between the plurality of light blocking patterns,
A denotes an optical density of the plurality of light blocking patterns, and
k is a constant in a range from about 0.35 to about 0.60.

2. The display device of claim 1, wherein the height of each of the plurality of light blocking patterns and the distance between the plurality of light blocking patterns satisfy the following inequality:
H/D>2.79,
wherein
H denotes the height of each of the plurality of light blocking patterns, and
D denotes the distance between the plurality of light blocking patterns.

3. The display device of claim 1, wherein the width of each of the light blocking patterns is in a range from about 0.97 μm to about 1.75 μm.

4. The display device of claim 1, wherein the optical density of the plurality of light blocking patterns is in a range from about 0.9 to about 1.67.

5. The display device of claim 1,
wherein the plurality of light blocking patterns comprise a black pigment and a blue pigment, and
wherein a ratio of a content of the black pigment and a content of the blue pigment is in a range from about 6:4 to about 8:2.

6. The display device of claim 1, wherein an area in a plan view, the plurality of light blocking patterns covers about 20% to about 30% of the emission area.

7. The display device of claim 1, wherein a reflectance of the plurality of light blocking patterns is less than or equal to about 5%.

8. The display device of claim 1, wherein light emitted at a viewing angle of greater than or equal to about 30° is blocked.

9. A method of manufacturing a display device, the method comprising:
forming a light-emitting element in an emission area on a substrate;
forming a plurality of preliminary light blocking patterns on the light-emitting element; and
forming a plurality of light blocking patterns, which are spaced apart from each other, by removing a portion of the plurality of preliminary light blocking patterns,
wherein each of the plurality of light blocking patterns having a width satisfying the following equation:
X=H/D×1/A×k,
wherein
X denotes the width of each of the plurality of light blocking patterns,
H denotes a height of each of the plurality of light blocking patterns,
D denotes a distance between the plurality of light blocking patterns,
A denotes an optical density of the plurality of light blocking patterns, and
k is a constant in a range from about 0.35 to about 0.60.

10. The method of claim 9, wherein the height of each of the plurality of light blocking patterns and the distance between the plurality of light blocking patterns satisfy the following inequality:
H/D>2.79,
wherein
H denotes the height of each of the plurality of light blocking patterns, and
D denotes the distance between the plurality of light blocking patterns.

11. The method of claim 9, wherein the width of each of the light blocking patterns is in a range from about 0.97 μm to about 1.75 μm.

12. The method of claim 9, wherein the optical density of the plurality of light blocking patterns is in a range from about 0.9 to about 1.67.

13. The method of claim 9, wherein in a plan view, the plurality of light blocking patterns covers about 20% to about 30% of the emission area.

14. The method of claim 9, wherein light emitted at a viewing angle of greater than or equal to about 30° is blocked.

15. The method of claim 9, wherein the forming the plurality of light blocking patterns comprises:
forming a plurality of first preliminary transmission patterns on the light-emitting element;
forming a light blocking layer covering the plurality of first preliminary transmission patterns;
forming the plurality of preliminary light blocking patterns by removing a portion of the light blocking layer;
forming the plurality of light blocking patterns by removing the portion of the plurality of preliminary light blocking patterns; and
forming a plurality of second preliminary transmission patterns between the plurality of light blocking patterns to form a transmission pattern.

16. The method of claim 15, wherein the portion of the light blocking layer is removed through an ashing process in the forming the plurality of preliminary light blocking patterns.

17. An electronic device comprising:
a display device; and
a processor which transmits an image data signal and an input control signal to the display device,
wherein the display device comprises:
a substrate comprising an emission area and a non-emission area adjacent to the emission area;
a light-emitting element in the emission area on the substrate; and
a plurality of light blocking patterns on the light-emitting element and spaced apart from each other,
wherein each of the plurality of light blocking patterns having a width satisfying the following equation:
X=H/D×1/A×k,
wherein
X denotes the width of each of the plurality of light blocking patterns,
H denotes a height of each of the plurality of light blocking patterns,
D denotes a distance between the plurality of light blocking patterns,
A denotes an optical density of the plurality of light blocking patterns, and
k is a constant in a range from about 0.35 to about 0.60.

18. The electronic device of claim 17, wherein the height of each of the plurality of light blocking patterns and the distance between the plurality of light blocking patterns satisfy the following inequality:
H/D>2.79,
wherein
H denotes the height of each of the plurality of light blocking patterns, and
D denotes the distance between the plurality of light blocking patterns.

19. The electronic device of claim 17, wherein the width of each of the light blocking patterns is in a range from about 0.97 μm to about 1.75 μm.

20. The electronic device of claim 17, wherein the optical density of the plurality of light blocking patterns is in a range from about 0.9 to about 1.67.
